(19) United States
(12) Patent Application Publication
(10) Pub. No.: US 2023/0160066 A1
(43) Pub. Date: May 25, 2023

(54) GAS SUPPLY ASSEMBLY, SUBSTRATE PROCESSING APPARATUS, NOZZLE, METHOD OF PROCESSING SUBSTRATE, METHOD OF MANUFACTURING SEMICONDUCTOR DEVICE, AND RECORDING MEDIUM

(71) Applicant: Kokusai Electric Corporation, Tokyo (JP)

(72) Inventors: Yoshitaka ABE, Toyama-shi (JP); Hironobu SHIMIZU, Toyama-shi (JP); Shinya MORITA, Toyama-shi (JP)

(73) Assignee: Kokusai Electric Corporation, Tokyo (JP)

(21) Appl. No.: 18/099,338

(22) Filed: Jan. 20, 2023

Related U.S. Application Data
(63) Continuation of application No. PCT/JP2021/033442, filed on Sep. 13, 2021.

(30) Foreign Application Priority Data
Sep. 18, 2020 (JP) 2020-157969

(51) Int. Cl. C23C 16/455

(52) U.S. Cl. CPC C23C 16/45578

(57) ABSTRACT

A technique makes it possible to prevent direct contact between a nozzle outer periphery and a nozzle adapter and to prevent generation of particles due to the direct contact. The technique includes: a nozzle that has an attaching portion formed on one end and discharges, into a processing chamber, a gas supplied to the attaching portion; a nozzle adapter that is disposed in the processing chamber and is clearance-fitted to an outer peripheral surface of the attaching portion with a predetermined gap; and a plurality of annular buffer members that is disposed in the attaching portion and abuts on the nozzle adapter, in which at least one of the annular buffer members is compressed and deformed in a radial direction of the corresponding annular buffer member in a state where the attaching portion of the nozzle is attached to the nozzle adapter.

### CROSS-REFERENCE TO RELATED PATENT APPLICATIONS

This application is a bypass continuation application of PCT International Application No. PCT/JP2021/033442, filed on Sep. 13, 2021, in the WIPO, the entire contents of which are hereby incorporated by reference.

### BACKGROUND

### Field

The present disclosure relates to a substrate processing apparatus, a gas supply assembly, a substrate processing method, and a method for manufacturing a semiconductor device.

### Description of the Related Art

As one of the substrate processing apparatuses, there is a batch type substrate processing apparatus that processes a predetermined number of substrates at a time. Furthermore, as one of the batch type substrate processing apparatuses, there is a vertical substrate processing apparatus including a vertical processing furnace. In order to introduce a processing gas into a quartz reaction tube constituting the processing furnace, a plurality of gas supply nozzles erected along an inner wall of the reaction tube is used. The gas supply nozzles are supported by a nozzle support member.

### SUMMARY

Since the gas supply nozzle made of quartz and the nozzle support member made of metal are fitted to each other, a slight gap may be formed between the quartz and the metal. Any gas other than the processing gas mixed into the nozzle through the gap causes generation of particles due to reaction, and the particles may fall onto a substrate along with a flow of the processing gas. Furthermore, direct contact between the quartz and the metal may cause generation of particles due to rubbing between the quartz and the metal, or breakage of the nozzle.

According to the present disclosure, there is provided a technique capable of preventing generation of particles due to a nozzle, particularly a connection structure between the nozzle and a nozzle adapter.

An aspect of the present disclosure provides a technique including: a nozzle that has an attaching portion formed on one end and discharges, into a processing chamber, a gas supplied to the attaching portion; a nozzle adapter that is disposed in the processing chamber and is clearance-fitted to an outer peripheral surface of the attaching portion with a predetermined gap; and a plurality of annular buffer members that is disposed in the attaching portion and abuts on the nozzle adapter, in which at least one of the annular buffer members is compressed and deformed in a radial direction of the corresponding annular buffer member in a state where the attaching portion of the nozzle is attached to the nozzle adapter.

### BRIEF DESCRIPTION OF THE DRAWINGS

FIG. 1 is a schematic oblique perspective view of a substrate processing apparatus suitably used in an embodiment of the present disclosure.

FIG. 2 is a diagram for explaining connection among a processing gas transfer pipe, a nozzle adapter, and a nozzle.

FIG. 3 is a perspective view for explaining a state where a nozzle is inserted into a nozzle adapter.

FIG. 4 is a cross-sectional view for explaining a state where a nozzle is inserted into a nozzle adapter.

FIG. 5 is a block diagram illustrating a schematic configuration of a controller of a substrate processing apparatus suitably used in an embodiment of the present disclosure.

FIG. 6 is a flowchart of a substrate processing step according to an embodiment of the present disclosure.

### DETAILED DESCRIPTION

Hereinafter, embodiments will be described with reference to the drawings. Note that, in the following description, the same components are denoted by the same reference numerals, and repeated description may be omitted. Note that, in order to make description clearer, the drawings may be schematically illustrated as compared with an actual aspect. However, the illustration is only an example and does not limit construe of the present disclosure. A dimensional relationship among elements, a ratio among the elements, and the like illustrated in the drawings do not necessarily coincide with actual ones. In addition, a dimensional relationship among elements, a ratio among the elements, and the like do not necessarily coincide among the plurality of drawings.

### Embodiment

(Configuration of Substrate Processing Apparatus)

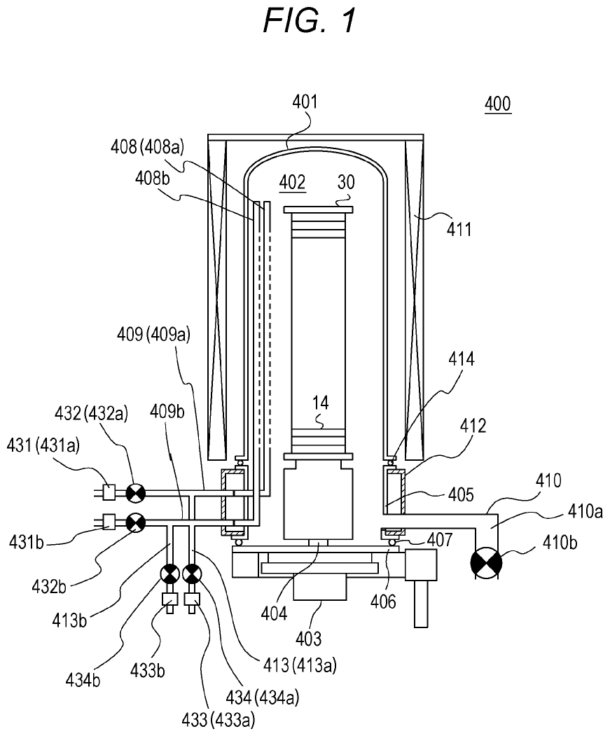

A substrate processing apparatus 400 will be described with reference to FIG. 1. FIG. 1 is a vertical cross-sectional view illustrating a configuration example of a substrate processing apparatus according to an embodiment of the present disclosure.

The substrate processing apparatus 400 includes a reaction tube 401. The reaction tube 401 is made of a heat-resistant non-metallic material such as quartz (SiO2) or silicon carbide (SiC) and is formed in a cylindrical shape with an upper end closed and a lower end opened. The lower end of the reaction tube 401 is supported by a manifold 405 via an O-ring 414. A space formed inside the reaction tube 401 and the manifold 405 is referred to as a processing space 402. The reaction tube 401 and the manifold 405 are collectively referred to as a processing chamber.

A furnace opening is formed in the manifold 405. The furnace opening is an entrance/exit through which the substrate support 30 passes when the substrate support 30 is inserted into the processing space 402. The manifold, the furnace opening, and the like are collectively referred to as a furnace opening portion.

The processing space 402 is configured such that wafers (semiconductor substrates) 14 supported in a horizontal attitude by the substrate support 30 are accommodated in a state of being aligned in multiple stages in the vertical direction in the processing space 402. The substrate support 30 accommodated in the processing space 402 is configured to be rotatable in a state where the plurality of wafers 14 is mounted on the substrate support 30 while maintaining airtightness in the processing space 402 by rotating a rotation shaft 404 by a rotation mechanism 403.

The manifold 405 is disposed below the reaction tube 401 concentrically with the reaction tube 401. The manifold 405 is made of a metallic material such as stainless steel, and has a cylindrical shape with an upper end and a lower end opened. The reaction tube 401 is vertically supported from a lower end side by this manifold 405. That is, the reaction tube 401 forming the processing space 402 stands in the vertical direction via the manifold 405.

The furnace opening is configured to be airtightly sealed by a seal cap 406 when a boat elevator (not illustrated) rises. A sealing member 407 such as an O-ring for airtightly sealing an inside of the processing space 402 is disposed between a lower end of the manifold 405 and the seal cap 406.

A nozzle 408 for injecting a processing gas, a purge gas, or the like into the processing space 402 and an exhauster 410 for exhausting a gas in the processing space 402 are connected to the manifold 405. The exhauster 410 includes an exhaust pipe 410a and an auto pressure controller (APC) 410b.

The nozzle 408 is a nozzle (injector) that discharges a gas into the processing chamber, and extends in an arrangement direction of the plurality of wafers loaded into the processing chamber. A plurality of gas supply holes is formed on a downstream side of the substrate processing apparatus nozzle 408, and an inside of the nozzle 408 is configured to be communicate with the reaction tube 401. The processing gas and the like are supplied from the gas supply holes to the processing space 402. The nozzle 408 is made of a non-metallic material having heat resistance, such as quartz (SiO2) or silicon carbide (SiC).

For example, two nozzles 408 are disposed. In this case, one nozzle is a first nozzle 408a that supplies a source gas, and the other nozzle is a second nozzle 408b that supplies a reactant gas that reacts with the source gas. Note that, here, the two supply pipes have been described, but the present disclosure is not limited thereto, and three or more supply pipes may be used depending on the type of process.

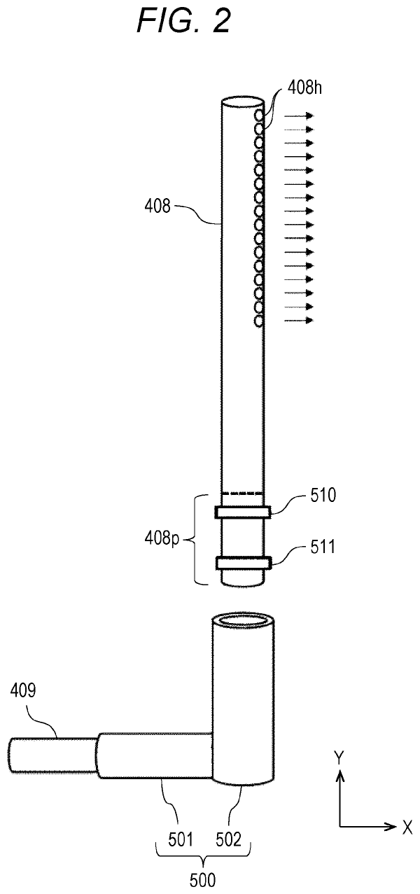

The nozzle 408 is connected to a processing gas transfer pipe 409 on an upstream side. The processing gas transfer pipe 409 transfers a gas from a gas source or the like to the nozzle 408. A first processing gas transfer pipe 409a is connected to the first nozzle 408a, and a second processing gas transfer pipe 409b is connected to the second nozzle 408b. A connection structure between the nozzle 408 and the processing gas transfer pipe 409 is a connection configuration as described with reference to FIGS. 2 to 4.

An inert gas transfer pipe 413 is connected to the processing gas transfer pipe 409. The inert gas transfer pipe 413 supplies an inert gas to the processing gas transfer pipe 409. The inert gas is, for example, a nitrogen (N2) gas, and acts as a carrier gas of the processing gas or as a purge gas of the reaction tube 401, the nozzle 408, or the processing gas transfer pipe 409.

A first inert gas transfer pipe 413a is connected to the first processing gas transfer pipe 409a, and a second inert gas transfer pipe 413b is connected to the second processing gas transfer pipe 409b.

In the processing gas transfer pipe 409, a mass flow controller 431 and a valve 432 that control a supply amount of the processing gas are disposed. In the first processing gas transfer pipe 409a, a mass flow controller 431a and a valve 432a are disposed. In the second processing gas transfer pipe 409b, a mass flow controller 431b and a valve 432b are disposed. The mass flow controller 431 and the valve 432 are collectively referred to as a processing gas supply controller.

In the inert gas transfer pipe 413, a mass flow controller 433 and a valve 434 that control a supply amount of the inert gas are disposed. In the first inert gas transfer pipe 413a, a mass flow controller 433a and a valve 434a are disposed. In the second inert gas transfer pipe 413b, a mass flow controller 433b and a valve 434b are disposed. The mass flow controller 433 and the valve 434 are collectively referred to as an inert gas supply controller.

The processing gas supply controller and the inert gas supply controller are collectively referred to as a gas supply controller.

A heater 411 serving as a heating means (heating mechanism) is disposed on an outer periphery of the reaction tube 401 concentrically with the reaction tube 401. The heater 411 is configured to heat an atmosphere in the processing space 402 such that an inside of the processing space 402 has a uniform or predetermined temperature distribution. The heater 411 is supported by a heater base (not illustrated).

A furnace opening box (scavenger) 412 for safely guiding a leaked gas to an exhaust passage is disposed on an outer periphery of the manifold 405.

Next, a connection configuration between the processing gas transfer pipe 409 and the nozzle 408 will be described with reference to FIGS. 2 to 4. FIG. 2 is a diagram for explaining connections among the processing gas transfer pipe 409, a nozzle adapter 500, and the nozzle 408.

As illustrated in FIG. 2, the processing gas transfer pipe 409 and the nozzle 408 are configured to be connected to each other via the L-shaped metal nozzle adapter 500. In a state where the processing gas transfer pipe 409 and the nozzle 408 are assembled to the nozzle adapter 500, a gas supplied to the processing gas transfer pipe 409 is supplied to the nozzle 408 through a pipe-shaped passage formed in the nozzle adapter 500, and is discharged into the processing chamber from a plurality of gas supply holes 408h formed in the nozzle 408.

The nozzle adapter 500 has a first adapter portion 501 which extends in the horizontal direction (first direction X) and to which the processing gas transfer pipe 409 is attached, and a second adapter portion 502 which is connected to the first adapter portion 501 and extends in the vertical direction (second direction Y) and to which the nozzle 408 is attached. The nozzle adapter 500 is also referred to as a metal port. The first adapter portion 501 is attached to an inlet port penetrating a side surface of the manifold 405, and a portion of the first adapter portion 501 in the vicinity of the second adapter portion 502 and the second adapter portion 502 are disposed in the processing chamber. A surface of the nozzle adapter 500 may be mirror-finished by electrolytic composite polishing.

The entire nozzle 408 is formed in a pipe, and discharges a gas from the gas supply holes 408h at substantially a right angle to a longitudinal direction (wafer arrangement direction). Note that the term “substantially right angle” includes a range of error occurring in manufacturing, and is, for example, 90 degrees±10 degrees. The nozzle 408 has an attaching portion 408p as an attacher formed in a straight pipe shape at one end thereof, and the attaching portion 408p is configured to be inserted into the second adapter portion 502. In the attaching portion 408p, two annular buffer members 510 and 511 are disposed at different positions in a longitudinal direction. The two annular buffer members 510 and 511 are disposed in close contact with an outer periphery of the attaching portion 408p, and are disposed so as to abut on the nozzle adapter 500. As the annular buffer members 510 and 511, for example, a ring-shaped fluorocarbon resin rubber (O-ring) having chemical resistance and heat resistance can be used. The O-ring can be molded using a polytetrafluoroethylene (PTFE)-based material with different physical properties such that stickiness, adhesiveness, or thermoplasticity is enhanced on an inner peripheral side abutting on the attaching portion 408p rather than an outer peripheral side abutting on the nozzle adapter 500. The nozzle 408, the nozzle adapter 500, and accessories thereof are collectively referred to as a gas supply assembly.

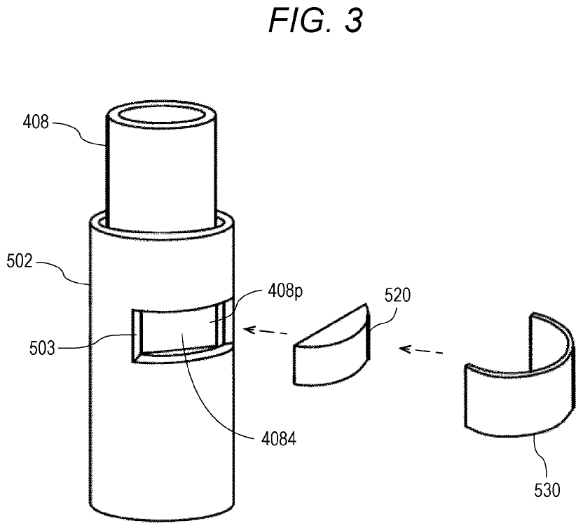

FIG. 3 is a perspective view illustrating a state where the attaching portion 408p of the nozzle 408 is inserted into the second adapter portion 502. In the second adapter portion 502, an opening 503 is formed. In the attaching portion 408p, a cutout portion 4084 is formed, and the nozzle 408 is inserted into the second adapter portion 502 such that the opening 503 and the cutout portion 4084 coincide with each other. The cutout portion 4084 is formed so as to make a direction of the nozzle 408 correct.

The opening 503 and the cutout portion 4084 are fixed by a semicircular metal block portion (also referred to as a fixing holder) 520 from a side surface side of the nozzle adapter 500. As a result, the direction of the nozzle 408 is adjustable, and a direction of a gas discharged from the plurality of gas supply holes 408h into the processing chamber is accurately adjusted. An outer side of the block portion 520 is fixed using a thin semicircular ring-shaped metal plate portion (also referred to as a ring holder) 530.

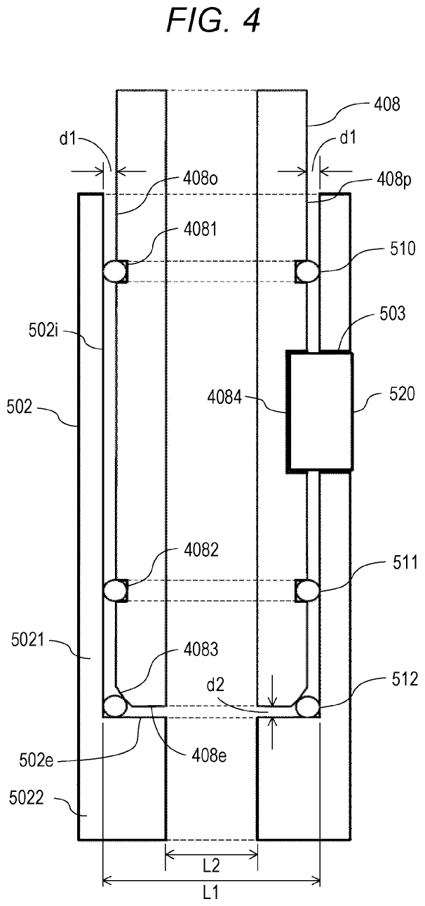

FIG. 4 is a cross-sectional view illustrating a state where the attaching portion 408p of the nozzle 408 is inserted into the second adapter portion 502.

The attaching portion 408p is formed in a circular pipe having a constant outer diameter. The second adapter portion 502 of the nozzle adapter 500 has an insertion area 5021 having a hole portion with a constant inner diameter L1 into which the attaching portion 408p is inserted, and a connection area 5022 disposed below the insertion area 5021 and having an opening with a diameter L2 narrower than the diameter L1. The diameter L1 is larger than the outer diameter of the attaching portion 408p, and the diameter L2 is preferably equal to the inner diameter of the attaching portion 408p.

In the attaching portion 408p, two angular U-shaped grooves 4081 and 4082 are formed on an outer peripheral surface 408o near both ends of the attaching portion 408p in the vertical direction (second direction Y). The two annular buffer members 510 and 511 are fitted into the two U-shaped grooves 4081 and 4082, respectively. Radially inner sides of the annular buffer members 510 and 511 are disposed in close contact with bottom portions of the U-shaped grooves 4081 and 4082, respectively. Radially outer sides of the annular buffer members 510 and 511 protrude from the U-shaped grooves 4081 and 4082, respectively, and abut on an inner peripheral surface 502i of the second adapter portion 502 of the nozzle adapter 500. At least one of the annular buffer members 510 and 511 is compressed and deformed in a radial direction of the corresponding annular buffer member (510 or 511) in a state where the attaching portion 408p of the nozzle 408 is attached to the second adapter portion 502 of the nozzle adapter 500.

In this manner, the outer peripheral surface 408o of the attaching portion 408p and the inner peripheral surface 502i of the second adapter portion 502 are clearance-fitted to each other with a predetermined gap d1. Each of the annular buffer member 510 and 511 is disposed so as to separate the outer peripheral surface 408o of the attaching portion 408p and the inner peripheral surface 502i of the second adapter portion 502 from each other by a predetermined amount (here, d1) to prevent the nozzle adapter 500 and the attaching portion 408p from coming into contact with each other.

A bottom surface 502e of the insertion area 5021 is formed flat at a boundary between the insertion area 5021 and the connection area 5022. A lower end of the attaching portion 408p is formed flat, but a corner portion at an outer periphery is chamfered, and a tapered surface 4083 is formed. An annular buffer member 512 is disposed between the bottom surface 502e and the tapered surface 4083. As the annular buffer member 512, for example, a ring-shaped fluorocarbon resin rubber (O-ring) having chemical resistance and heat resistance can be used. The annular buffer member 512 is disposed between the bottom surface portion 408e formed at the lower end of the attaching portion 408p and the bottom surface 502e of the insertion area 5021 so as to maintain a predetermined gap d2.

In this manner, the annular buffer member 512 is disposed on the bottom surface 502e such that the bottom surface portion 408e of the attaching portion 408p and the bottom surface 502e of the insertion area 5021 do not come into contact with each other in a state where the attaching portion 408p of the nozzle 408 is attached to the second adapter portion 502 of the nozzle adapter 500.

Note that the connection area 5022 is connected to the first adapter portion 501 of the nozzle adapter 500. A flow path bent at a right angle is formed inside the connection area 5022, and one end of the flow path opens to the insertion area 5021 and the other end communicates with a flow path of the first adapter portion 501.

The cutout portion 4084 is formed between the U-shaped grooves 4081 and 4082 of the attaching portion 408p, and the attaching portion 408p is attached to the second adapter portion 502 such that the opening 503 corresponds to the cutout portion 4084. The opening 503 and the cutout portion 4084 are fixed by the block portion 520. That is, movement and rotation in the vertical direction are restricted.

As described above, since the two annular buffer members 510 and 511 are disposed at an upper portion and a lower portion of the attaching portion 408p, inclination of the quartz nozzle 408 can be prevented. The two annular buffer members disposed on the outer periphery of the attaching portion 408p are desirably disposed so as to be far away from each other as much as possible from a viewpoint of suppressing the inclination. Since the gas supply hole 408h injects a gas laterally, a reaction force of the injection is generated in a direction of inclining the nozzle 408. However, even if the gas is supplied to the nozzle 408 in a pulse shape, the inclination and swing can be sufficiently suppressed. In addition, even if the gap d1 is widened by a difference in coefficient of thermal expansion due to exposure to high temperature when the wafer is processed, the attaching portion 408p is pushed by the annular buffer members 510 and 511 with substantially the same force from all directions. Therefore, the attaching portion 408p can maintain an upright state.

As a result, it is possible to prevent direct contact between the metal of the second adapter portion 502 of the nozzle adapter 500 and the quartz of the nozzle 408 due to the inclination. Since direct contact can be prevented, generation of particles due to contact can be prevented. Furthermore, among the plurality of annular buffer members, the annular buffer members 511 and 512 disposed below the opening 503 can improve airtightness between the nozzle 408 and the nozzle adapter 500. Note that the annular buffer member 512 is not essential from a viewpoint of preventing inclination. The number of particles generated by direct contact between the bottom surface portion 408e and the bottom surface 502e may be sufficiently small as to be allowable. The airtightness can be sufficiently maintained by the annular buffer member 511 alone.

(Controller)

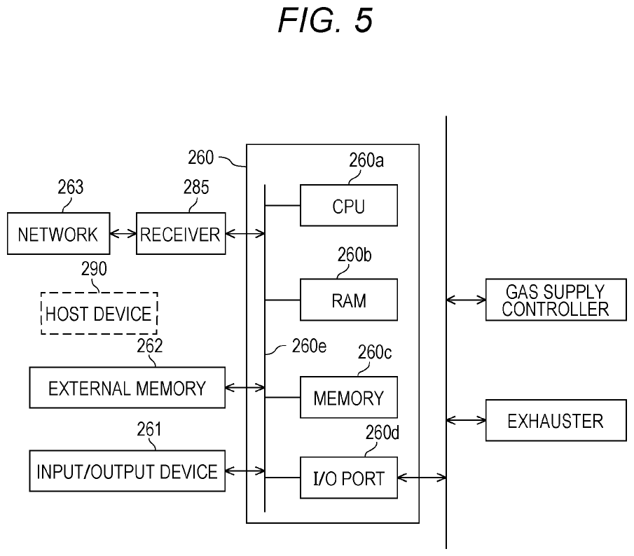

FIG. 5 is a block diagram schematically illustrating a configuration example of a controller included in a substrate processing apparatus according to an embodiment of the present disclosure. The controller 260 is configured as a computer including a central processing unit (CPU) 260a, a random access memory (RAM) 260b, a memory 260c, and an I/O port 260d.

The RAM 260b, the memory 260c, and the I/O port 260d are configured to be capable of exchanging data with the CPU 260a via an internal bus 260e. An input/output device 261 configured as, for example, a touch panel and an external memory 262 are configured to be connectable to the controller 260. From the input/output device 261, information can be input to the controller 260. The input/output device 261 also displays and outputs information under control of the controller 260. Furthermore, a network 263 is configured to be connectable to the controller 260 through a receiver 285. This means that the controller 260 is also connectable to a host device 290 such as a host computer present on the network 263.

The memory 260c is constituted by, for example, a flash memory or a hard disk drive (HDD). In the memory 260c, a control program for controlling an operation of the substrate processing apparatus 400, a process recipe describing procedures, conditions, and the like for substrate processing, calculation data, processing data, and the like generated in a process until setting a process recipe used for processing on the wafer 14, and the like are stored in a readable manner. Note that the process recipe is a combination formed so as to cause the controller 260 to execute procedures in a substrate processing step to obtain a predetermined result, and functions as a program. Hereinafter, the process recipe, the control program, and the like are also collectively and simply referred to as a program. Note that, in the present specification, the term “program” may include only a process recipe alone, only a control program alone, or both of these. The RAM 260b is configured as a memory area (work area) in which a program, calculation data, processing data, and the like read by the CPU 260a are temporarily stored.

The CPU 260a serving as a calculator is configured to read and execute a control program from the memory 260c, and to read a process recipe from the memory 260c in response to input of an operation command from the input/output device 261, or the like. In addition, the CPU 260a is configured to compare and calculate a set value input from the receiver 285 with the process recipe and the control data stored in the memory 260c to be able to calculate calculation data. In addition, the CPU 260a is configured to be able to execute determination processing and the like of corresponding processing data (process recipe) from the calculation data. In addition, the CPU 260a is configured to perform operation control on each of the units in the substrate processing apparatus 10 in accordance with the content of the read process recipe.

Note that the controller 260 is not limited to a configuration as a dedicated computer, and may be configured as a general-purpose computer. For example, the controller 260 according to the present embodiment can be configured by preparing an external memory (for example, a magnetic tape, a magnetic disk such as a flexible disk or a hard disk, an optical disk such as a CD or a DVD, a magneto-optical disk such as an MO, or a semiconductor memory such as a USB memory or a memory card) 262 storing the above-described program, and installing the program in a general-purpose computer using the external memory 262. Note that the means for supplying the program to the computer is not limited to the supply via the external memory 262. For example, the program may be supplied using a communication means such as the network 263 (the Internet or a dedicated line) without going through the external memory 262. Note that the memory 260c and the external memory 262 are configured as computer-readable recording media. Hereinafter, these are also collectively referred to simply as a recording medium. Note that, in the present specification, the term “recording medium” may include only the memory 260c alone, only the external memory 262 alone, or both of these.

(Substrate Processing Step)

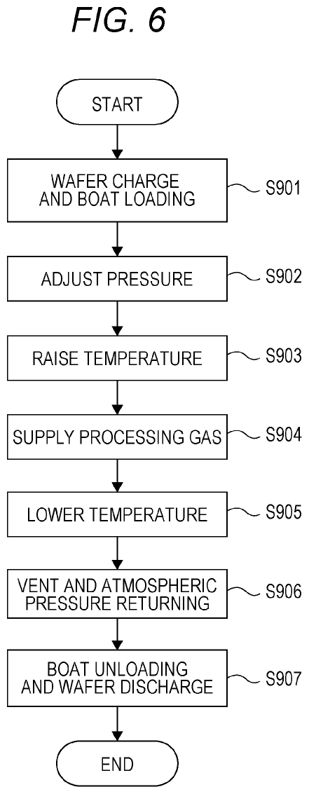

A substrate processing step according to an embodiment of the present disclosure will be described with reference to FIG. 6. Note that the substrate processing step according to the present embodiment is a method for forming a film on a surface of the wafer 14 using, for example, a chemical vapor deposition (CVD) method, and is performed as one step of a process for manufacturing a semiconductor device. Note that, in the following description, an operation of each of the units constituting the substrate processing apparatus is controlled by the controller 260.

In a substrate loading step S901, the plurality of wafers 14 is loaded into the substrate support 30 (wafer charge). Then, the substrate support 30 supporting the plurality of wafers 14 is lifted by a boat elevator (not illustrated) and loaded into the processing space 402 (boat loading). In this state, the seal cap 406 seals a lower end of the manifold 405 via the O-ring 407.

Subsequently, in a pressure adjusting step S902, the atmosphere in the processing space 402 is exhausted from the exhauster 410 such that an inside of the processing space 402 has a desired pressure (degree of vacuum). At this time, the pressure in the processing space 402 is measured, and the degree of opening of the APC valve 410b disposed in the exhauster 410 is feedback-controlled based on the measured pressure. The pressure adjusting step S902 is continued until a film forming step S904 is completed.

Subsequently, in a temperature adjusting step S903, the inside of the processing space 402 is heated by the heater 411 to a desired temperature. At this time, the degree of energization to the heater 411 is feedback-controlled based on temperature information detected by a temperature sensor such that the inside of the processing space 402 has a predetermined temperature distribution. Then, the substrate support 30 is rotated by the rotation mechanism 403 to rotate the wafers 14. The temperature adjusting step S903 is continued until the film forming step S904 is completed. Either the temperature adjusting step S903 or the pressure adjusting step S902 may be started first.

Subsequently, in the film forming step S904, a gas is supplied onto each of the wafers 14 to form a desired film. For example, a silicon source gas serving as a first processing gas from the first nozzle 408a and a nitrogen source gas serving as a second processing gas from the second nozzle 408b are supplied continuously or alternately. The silicon source gas and the nitrogen source gas supplied to the processing space 402 react with each other in a gas phase or on a surface of each of the wafers 14 to form a silicon nitride film on each of the wafers 14. At this time, the gas flows in each of the first nozzle 408a and the second nozzle 408b at a speed close to the sound speed, and a static pressure therein can be lower than that in the processing space 402.

Subsequently, in a temperature lowering step S905, the temperature adjustment in step S903 continued during the film forming processing is stopped or reset to a lower temperature as necessary, and the temperature in the processing chamber 201 is gradually lowered.

Subsequently, in a vent and atmospheric pressure returning step S906, the degree of opening of the APC valve 410b is reduced or fully closed, and a purge gas is supplied into the processing space 402 until the pressure in the processing space 402 reaches the atmospheric pressure. The purge gas is, for example, an N2 gas, and can be supplied to the processing space via the inert gas transfer pipes 413a and 413b. Note that this step S906 may be started immediately after the film forming step S904 is completed. The temperature lowering step S905 and the vent and atmospheric pressure returning step S906 may be performed in parallel, or the starting order may be changed.

Finally, in a substrate unloading step S907, the wafer 14 on which the film has been formed is unloaded from the inside of the processing space 402 by a procedure reverse to the substrate loading step S901.

According to the present embodiment, the following one or more effects can be obtained.

(1) The substrate processing apparatus 400 includes two annular buffer members (O-rings) 510 and 511 disposed in close contact with an outer periphery of the attaching portion 408p and abutting on the nozzle adapter 500. As a result, it is possible to prevent the outer peripheral surface of the nozzle 408 serving as a nozzle from coming into direct contact with the metal nozzle adapter 500, and to prevent generation of particles due to the contact. At the same time, airtightness between the nozzle 408 and the metal nozzle adapter 500 is improved, and mixing of impurities from the outside of the nozzle 408 and leakage from the inside of the nozzle 408 can be suppressed.

(2) Since the nozzle adapter 500 is attached to the nozzle 408 by hand in a state where the nozzle 408 is stably held outside the processing chamber, a large force is not applied to the attaching portion 408p, and there is little possibility that the outer peripheral surface of the nozzle 408 and the nozzle adapter 500 come into contact with each other during the attachment and that particles are generated due to the contact.

(3) Coating may be applied to the surface of the quartz nozzle 408, but the effect of suppressing contact between the outer peripheral surface of the nozzle 408 and the inner peripheral surface of the nozzle adapter 500 and the effect of suppressing generation of particles are not reduced due to appropriate elasticity and adhesion of the annular buffer members 510, 511, and 512 even if the surface roughness of the coating is rougher than that of a normal fired quartz surface.

(4) Since the conventional nozzle is merely pressed against the nozzle adapter 500 by its own weight, the nozzle slightly moves up and down (in the axial direction) due to a relationship between the pressure in the processing chamber and the gas pressure in the nozzle particularly when a gas is intermittently supplied, and particles may be generated even during the processing in the substrate processing step. Since the annular buffer members 510, 511 and 512 are disposed, the vertical (axial) movement is suppressed, and even if the movement occurs, direct contact between the outer peripheral surface of the nozzle 408 and the metal nozzle adapter 500 and a gas flow can be prevented, and generation of particles can be prevented.

(5) When the nozzle 408 is inserted into the nozzle adapter 500, only the annular buffer members 510 and 511 and the nozzle adapter come into contact with each other, friction is small, and attachment can be easily performed. In addition, vertical movement is suppressed by appropriate friction, and therefore it is possible to prevent the nozzle 408 from being accidentally dropped.

Although specific description has been made above based on Examples, the present disclosure is not limited to the above embodiments and Examples, and it goes without saying that various modifications can be made. For example, the angular U-shaped grooves 4081 and 4082 includes dovetail grooves and are not limited to those formed in the nozzle 408, and may be formed in the nozzle adapter 500.

According to the above technique, since the annular buffer member is disposed, it is possible to suppress generation of particles derived from the nozzle.

What is claimed is:

1. A gas supply assembly comprising:
a nozzle that has an attaching portion on one end and discharges a gas supplied to the attaching portion;
a nozzle adapter that is attachable to and detachable from a processing chamber of a substrate processing apparatus and is clearance-fitted to an outer peripheral surface of the attaching portion with a predetermined gap; and
a plurality of annular buffer members disposed in the attaching portion and abutting the nozzle adapter, wherein
at least one of the annular buffer members is compressed and deformed in a radial direction of the corresponding annular buffer member in a state where the attaching portion of the nozzle is attached to the nozzle adapter.

2. The gas supply assembly of claim 1, wherein:
the plurality of annular buffer members is disposed at different positions in a longitudinal direction of the attaching portion.

3. The gas supply assembly of claim 1, wherein:
the plurality of annular buffer members is disposed in grooves formed on an outer periphery near both ends of the attaching portion, respectively, and protrudes from the grooves, respectively.

4. The gas supply assembly of claim 1, wherein:
the attaching portion is formed in a pipe shape, and the annular buffer members are disposed to separate an outer peripheral surface of the attaching portion of the nozzle and the nozzle adapter from each other by a predetermined amount to prevent the outer peripheral surface and the nozzle adapter from coming into contact with each other.

5. The gas supply assembly of claim 2, wherein:
a fixing holder for making a direction of the nozzle correct is disposed between the annular buffer members.

6. The gas supply assembly of claim 1, wherein:
the nozzle adapter supports the nozzle in an upright state.

7. The gas supply assembly of claim 6, wherein:
the attaching portion has a constant outer diameter in a longitudinal direction, and a portion of the nozzle adapter into which the attaching portion is inserted has a constant inner diameter.

8. The gas supply assembly of claim 6, wherein:
one of the plurality of annular buffer members is disposed at a lower end of the attaching portion to prevent a bottom of the nozzle from coming into contact with the nozzle adapter.

9. The gas supply assembly of claim 1, wherein:
the nozzle extends in an arrangement direction of a plurality of substrates loaded into the processing chamber, and discharges a gas at a substantially right angle to the arrangement direction.

10. The gas supply assembly of claim 1, wherein:
the nozzle adapter is made of metal, and the nozzle is made of non-metal.

11. A substrate processing apparatus comprising the gas supply assembly of claim 1, wherein the nozzle adapter is installed in the processing chamber of the processing apparatus.

12. A nozzle comprising:
an attaching portion formed in a straight pipe at one end and which is inserted into a nozzle adapter, and into which a gas is supplied from the nozzle adapter;
a gas supply hole that discharges the gas supplied to the attaching portion at a substantially right angle to a longitudinal direction of the attaching portion; and
two grooves which are formed on an outer periphery near both ends of the attaching portion and to which annular buffer members are attached, respectively.

13. The nozzle of claim 12, wherein:
the grooves are formed in U-shape, and
the entire nozzle is made of non-metal.

14. A substrate processing method comprising:
loading a substrate into a processing chamber of a substrate processing apparatus including: a nozzle having an attaching portion formed on one end and discharges, into the processing chamber, a gas supplied to the attaching portion; a nozzle adapter that is disposed in the processing chamber and is clearance-fitted to an outer peripheral surface of the attaching portion with a predetermined gap; and a plurality of annular buffer members that is disposed in the attaching portion and abuts on the nozzle adapter, in which at least one of the annular buffer members is compressed and deformed in a radial direction of the corresponding annular buffer member in a state where the attaching portion of the nozzle is attached to the nozzle adapter; and
discharging the gas from the nozzle to the substrate in the processing chamber.

15. The substrate processing method of claim 14, further including manufacturing a semiconductor device.

16. A non-transitory, computer readable medium having instructions stored thereon that, when executed, perform a method comprising:
loading a substrate into a processing chamber of a substrate processing apparatus including: a nozzle that has having an attaching portion formed on one end and discharges, into the processing chamber, a gas supplied to the attaching portion; a nozzle adapter that is disposed in the processing chamber and is clearance-fitted to an outer peripheral surface of the attaching portion with a predetermined gap; and a plurality of annular buffer members that is disposed in the attaching portion and abuts on the nozzle adapter, in which at least one of the annular buffer members is compressed and deformed in a radial direction of the corresponding annular buffer member in a state where the attaching portion of the nozzle is attached to the nozzle adapter; and
discharging the gas from the nozzle to the substrate in the processing chamber.
